(19) United States
(12) Patent Application Publication
(10) Pub. No.: US 2025/0180651 A1
(43) Pub. Date: Jun. 5, 2025

(54) ONLINE ESTIMATION OF CURRENT-DEPENDENT NON-LINEAR EQUIVALENT CIRCUIT MODEL PARAMETERS OF A BATTERY

(71) Applicant: Cirrus Logic International Semiconductor Ltd., Edinburgh (GB)

(72) Inventor: Samuel P. EBENEZER, Gilbert, AZ (US)

(73) Assignee: Cirrus Logic International Semiconductor Ltd., Edinburgh (GB)

(21) Appl. No.: 18/628,374

(22) Filed: Apr. 5, 2024

Related U.S. Application Data
(60) Provisional application No. 63/605,031, filed on Dec. 1, 2023.

(51) Int. Cl. G01R 31/367; G01R 31/3842; G01R 31/389

(52) U.S. Cl. CPC G01R 31/367; G01R 31/3842; G01R 31/389

(57) ABSTRACT

A method for estimating current-dependent non-linear equivalent circuit model (ECM) parameters of a battery may include measuring a battery voltage across terminals of the battery and a battery current drawn from the battery, deriving linear ECM parameters for modeling a linear ECM of the battery with multiple resistive-capacitive elements with different time constants to characterize temporal behaviors of the battery, continuously tracking an impedance for each of the multiple resistive-capacitive elements and an open circuit voltage of the battery, continuously monitoring the battery current to detect high current events, continuously tracking a deviation for each of the multiple resistive-capacitive elements during the high current events, and deriving non-linear online ECM parameters based on the linear ECM parameters and the deviations for the multiple resistive-capacitive elements during the high current events.

### RELATED APPLICATIONS

The present disclosure claims priority to U.S. Provisional Patent Application Ser. No. 63/605,031, filed Dec. 1, 2023, which is incorporated by reference herein in its entirety.

The present disclosure is also related to U.S. patent application Ser. No. 18/308,420, filed Apr. 27, 2023, U.S. patent application Ser. No. 18/308,449, filed Apr. 27, 2023, and U.S. patent application Ser. No. 18/455,253, filed Aug. 24, 2023, all of which are incorporated by reference herein in their entireties.

### FIELD OF DISCLOSURE

The present disclosure relates in general to circuits for electronic devices, including without limitation personal portable devices such as wireless telephones and media players, and more specifically, to online characterization of battery model parameters with augmented dynamic stimulus and estimation of equivalent circuit model parameters of a battery.

### BACKGROUND

Portable electronic devices, including wireless telephones, such as mobile/cellular telephones, tablets, cordless telephones, mp3 players, and other consumer devices, are in widespread use. Such a portable electronic device may include a battery (e.g., a lithium-ion battery) for powering components of the portable electronic device.

In operation, the terminal voltage of a battery may droop under a load current due to internal output impedance of the battery. Such output impedance may be modeled in a number of suitable manners, including with an equivalent circuit model of a series of parallel-coupled resistors and capacitors. Knowledge of the detailed impedance of a battery may be useful for fuel-gauging algorithms (e.g., for determining a battery open-circuit voltage and state of charge, predicting power limits, and/or deriving safety limits or safe operation limits of the battery (e.g., a maximum voltage and maximum current of the battery terminal)).

There may exist advantages in using a system load current drawn from a battery in order to perform in-situ characterization of parameters of the equivalent circuit model, as such an approach avoids time-consuming and computationally-expensive offline characterization that measures impedance of a battery across a frequency range. Moreover, a battery is a highly non-linear dynamic system and the offline characterization will not work well under various working condition of the battery. However, spectrally-rich stimulus may be required to accurately estimate equivalent circuit model parameters, and system load current is not guaranteed to contain spectrally-rich content at all times. Further, an equivalent circuit model of a battery may be substantially non-linear, and thus modelling such non-linearities may also be desirable. For example, the equivalent circuit model parameters are subjected to change as a function of the amplitude of the load current that is drawn from a battery.

### SUMMARY

In accordance with the teachings of the present disclosure, one or more disadvantages and problems associated with existing approaches to modeling a battery with an equivalent circuit model may be reduced or eliminated.

In accordance with embodiments of the present disclosure, a method for estimating current-dependent non-linear equivalent circuit model (ECM) parameters of a battery may include measuring a battery voltage across terminals of the battery and a battery current drawn from the battery, deriving linear ECM parameters for modeling a linear ECM of the battery with multiple resistive-capacitive elements with different time constants to characterize temporal behaviors of the battery, continuously tracking an impedance for each of the multiple resistive-capacitive elements and an open circuit voltage of the battery, continuously monitoring the battery current to detect high current events, continuously tracking a deviation for each of the multiple resistive-capacitive elements during the high current events, and deriving non-linear online ECM parameters based on the linear ECM parameters and the deviations for the multiple resistive-capacitive elements during the high current events.

In accordance with these and other embodiments of the present disclosure, a method for modelling an equivalent circuit for a battery may include determining equivalent circuit model (ECM) parameters to model the battery wherein the ECM parameters include current-dependent non-linear online ECM parameters and deriving the current dependent non-linear online ECM parameters by using linear ECM parameters and resistive-capacitive (RC) pair impedance deviation estimates for RC pairs of the ECM multiple amplitudes of the current wherein the RC pair impedance deviation estimates are determined by continuously tracking an impedance and an impedance deviation for each RC pair.

In accordance with these and other embodiments of the present disclosure, a method for estimating current-dependent non-linear equivalent circuit model (ECM) parameters of a battery may include measuring a battery voltage across terminals of the battery and a battery current drawn from the battery, deriving linear ECM parameters for modeling a linear ECM of the battery with multiple resistive-capacitive elements with different time constants to characterize temporal behaviors of the battery, continuously tracking an impedance for each of the multiple resistive-capacitive elements and an open circuit voltage of the battery, continuously monitoring the battery current to detect high current events, and in the absence of detection of high-current events augmenting the battery current with a sink current to generate an augmented current, continuously tracking the deviation for each of the multiple resistive-capacitive elements based on the augmented current, and deriving non-linear online ECM parameters based on the linear ECM parameters and the deviations for the multiple resistive-capacitive elements based on the augmented current.

In accordance with these and other embodiments of the present disclosure, a system for estimating current-dependent non-linear equivalent circuit model (ECM) parameters of a battery may include measurement circuitry for measuring a battery voltage across terminals of the battery and a battery current drawn from the battery, a linear ECM for deriving linear ECM parameters to for model the linear ECM of the battery with multiple resistive-capacitive elements with different time constants to characterize temporal behaviors of the battery, a high-current detection subsystem for continuously monitoring the battery current to detect high current events, an impedance deviation tracker for continuously tracking an impedance for each of the multiple resistive-capacitive elements and an open circuit voltage of the battery and continuously tracking a deviation for each of the multiple resistive-capacitive elements during the high current events, and a non-linear ECM for deriving non-linear online ECM parameters based on the linear ECM parameters and the deviations for the multiple resistive-capacitive elements during the high current events.

In accordance with these and other embodiments of the present disclosure, a system for modelling an equivalent circuit for a battery may include an equivalent circuit model (ECM) for determining ECM parameters to model the battery wherein the ECM parameters include current-dependent non-linear online ECM parameters and a non-linear ECM for deriving the current dependent non-linear online ECM parameters by using linear ECM parameters and resistive-capacitive (RC) pair impedance deviation estimates for RC pairs of the ECM multiple amplitudes of the current wherein the RC pair impedance deviation estimates are determined by continuously tracking an impedance and an impedance deviation for each RC pair.

In accordance with these and other embodiments of the present disclosure, a method for estimating current-dependent non-linear equivalent circuit model (ECM) parameters of a battery may include measurement circuitry for measuring a battery voltage across terminals of the battery and a battery current drawn from the battery, a linear ECM for deriving linear ECM parameters to for model the linear ECM of the battery with multiple resistive-capacitive elements with different time constants to characterize temporal behaviors of the battery, an impedance deviation tracker for continuously tracking an impedance for each of the multiple resistive-capacitive elements and an open circuit voltage of the battery, a high-current detection subsystem for continuously monitoring the battery current to detect high current events, and in the absence of detection of high-current events: a dependent current source for augmenting the battery current with a sink current to generate an augmented current, the impedance deviation tracker further for continuously tracking the deviation for each of the multiple resistive-capacitive elements based on the augmented current, and the non-linear ECM for further deriving non-linear online ECM parameters based on the linear ECM parameters and the deviations for the multiple resistive-capacitive elements based on the augmented current.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example power delivery network, in accordance with embodiments of the present disclosure;

FIG. 2 illustrates an example graph of an open circuit voltage of a battery versus the battery's state of charge, in accordance with embodiments of the present disclosure;

FIG. 3 illustrates a circuit diagram of selected components of an equivalent circuit model for a battery, in accordance with embodiments of the present disclosure;

FIG. 4 illustrates a block diagram of a system for online characterization of an equivalent circuit model of a battery using sub-bands and augmented dynamic current stimulus, in accordance with embodiments of the present disclosure;

FIGS. 5A and 5B illustrate a block diagram of an example architecture of an algorithm for calculating parameters of an equivalent circuit model of a battery, in accordance with embodiments of the present disclosure;

FIG. 6 illustrates a block diagram of an example architecture of a tracker for calculating parameters of an equivalent circuit model of a battery, in accordance with embodiments of the present disclosure;

FIG. 7 illustrates a block diagram of selected components of a system for online characterization of an equivalent circuit model of a battery using sub-bands and augmented dynamic current stimulus, in accordance with embodiments of the present disclosure;

FIG. 8 illustrates a high-level block diagram of selected components of a system for online characterization of a current-dependent non-linear equivalent circuit model of a battery, in accordance with embodiments of the present disclosure; and

FIG. 9 illustrates a detailed-level block diagram of selected components of a system for online characterization of a current-dependent non-linear equivalent circuit model of a battery, in accordance with embodiments of the present disclosure.

### DETAILED DESCRIPTION

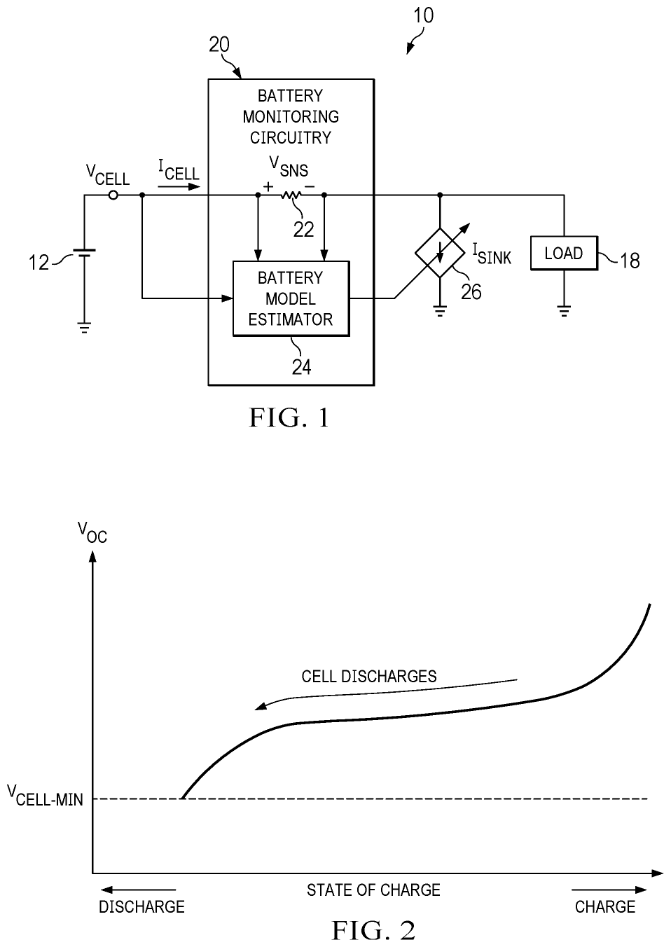

FIG. 1 illustrates a block diagram of selected components of an example power delivery network 10, in accordance with embodiments of the present disclosure. In some embodiments, power delivery network 10 may be implemented within a portable electronic device, such as a smart phone, tablet, game controller, and/or other suitable device.

As shown in FIG. 1, power delivery network 10 may include a battery 12 and a load 18. As shown in FIG. 1, when loaded by load 18, battery 12 may generate a battery voltage V_{CELL} across its terminals and deliver a battery current I_{CELL} to load 18. In some embodiments, battery 12 may comprise a lithium-ion battery. Load 18 may represent any electric component, electronic component, and/or combination thereof. For example, load 18 may include any suitable functional circuits or devices of power delivery network 10, including without limitation power converters, processors, audio coder/decoders, amplifiers, display devices, etc. Further, although not explicitly shown in FIG. 1, power delivery network 10 may also include control circuitry for controlling operation of battery 12 and/or load 18.

As also shown in FIG. 1, power delivery network 10 may include battery monitoring circuitry 20. Battery monitoring circuitry 20 may include any suitable system, device, or apparatus configured to monitor battery voltage V_{CELL} and battery current I_{CELL}. Further, battery monitoring circuitry 20 may include a battery model estimator 24 configured to monitor battery voltage V_{CELL} and a sense voltage V_{SNS} across a sense resistor 22 indicative of battery current I_{CELL}, and based thereon, estimate a battery impedance model for battery 12, as described in greater detail below. Battery model estimator 24 may be implemented with a processing device, including without limitation a microprocessor, digital signal processor, application-specific integrated circuit, field-programmable gate array, electrically-erasable programmable read only memory, complex programmable logic device, and/or other suitable processing device. In some embodiments, battery monitoring circuitry 20 may monitor a temperature associated with battery 12, and battery model estimator 24 may estimate the impedance model based on battery voltage V_{CELL}, a sense voltage V_{SNS}, and the sensed temperature.

As further shown in FIG. 1, power delivery network 10 may further include a dependent current source 26 controlled by battery model estimator 24 and configured to generate a sink current I_{SINK}. Control of sink current I_{SINK} by battery model estimator 24 is described in greater detail below.

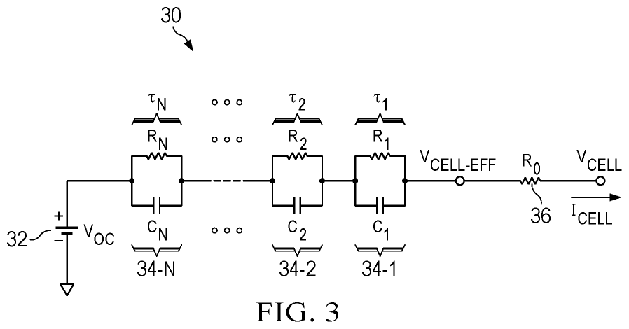

Lithium-ion batteries are typically known to operate from 4.5 V down to 3.0 V, known as an open circuit voltage V_{OC} of the battery (e.g., battery 12). As a battery discharges due to a current drawn from the battery, the state of charge of the battery may also decrease, and open circuit voltage V_{OC} (which may be a function of state of charge) may also decrease as a result of electrochemical reactions taking place within the battery, as shown in FIG. 2. Outside the range of 3.0 V and 4.5 V for open circuit voltage V_{OC}, the capacity, life, and safety of a lithium-ion battery may degrade. For example, at approximately 3.0 V, approximately 95% of the energy in a lithium-ion cell may be spent (i.e., state of charge is 5%), and open circuit voltage V_{OC} would be liable to drop rapidly if further discharge were to continue. Below approximately 2.4 V, metal plates of a lithium-ion battery may erode, which may cause higher internal impedance for the battery, lower capacity, and potential short circuit. Thus, to protect a battery (e.g., battery 12) from over-discharging, many portable electronic devices may prevent operation below a predetermined end-of-discharge voltage. Knowledge of the output impedance may be useful in determining open circuit voltage V_{OC} and other parameters of battery 12.

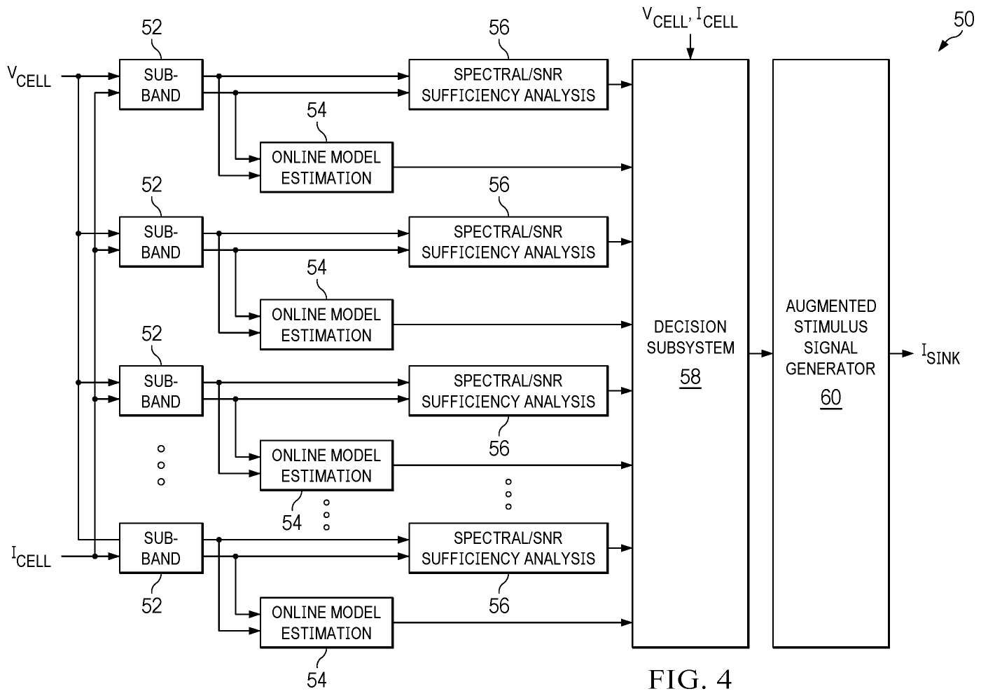

FIG. 3 illustrates a block diagram of selected components of an equivalent circuit model 30 for battery 12, in accordance with embodiments of the present disclosure. As shown in FIG. 3, battery 12 may be modeled as having a battery cell 32 having an open circuit voltage V_{OC} in series with a plurality of parallel resistive-capacitive sections 34 (e.g., parallel resistive-capacitive sections 34-1, 34-2, . . . , 34-N) and further in series with an equivalent series resistance 36 of battery 12, such equivalent series resistance 36 having a resistance of R₀. Resistances R₁, R₂, . . . . R_{N}, and respective capacitances C₁, C₂, . . . , CN may model battery chemistry-dependent time constants τ₁, τ₂, . . . , τ_{N}, that may be lumped with open circuit voltage V_{OC} and equivalent series resistance 36. The series of impedance sections represented by resistive-capacitive sections 34 and equivalent series resistance 36 may represent diffusion processes that occur at different rates inside battery 12. Cutoff frequencies of parallel resistive-capacitive sections 34 may respectively be given by:

$$\begin{matrix}{f}_{c 1} = \frac{1}{{τ}_{1}} = \frac{1}{2 π {R}_{1} {C}_{1}} ; \\ {f}_{c 2} = \frac{1}{{τ}_{2}} = \frac{1}{2 π {R}_{2} {C}_{2}} ; \\ … \\ {f}_{c N} = \frac{1}{{τ}_{3}} = \frac{1}{2 π {R}_{N} {C}_{N}} ;\end{matrix}$$

wherein π represents the well-known mathematical constant defined as the ratio of a circle's circumference to its diameter, and wherein parallel resistive-capacitive sections 34 are ordered such that f_{cN}< . . . <f_{c2}<f_{c1}.

Notably, an electrical node depicted with voltage V_{CELL-EFF} in FIG. 3 may capture the time varying discharge behavior of battery 12, and battery voltage V_{CELL} may be an actual voltage seen across the output terminals of battery 12. Voltage V_{CELL}-EFF may not be directly measurable, and thus battery voltage V_{CELL} may be the only voltage associated with battery 12 that may be measured to evaluate battery state of health. Also of note, at a current draw of zero (e.g., I_{CELL}=0), battery voltage V_{CELL} may be equal to voltage V_{CELL-EFF} which may in turn be equal to an open circuit voltage V_{OC} at a given state of charge, provided that enough time has passed with the current at zero, such that all of the voltages on capacitors of resistive-capacitive sections 34 have discharged to zero.

Battery behavior may change due to various factors, including temperature, state of charge, charge/discharge current amplitude and/or frequency, and others. Changes in such factors may change electro-chemical states of the battery, and these dynamic behaviors may result in corresponding changes in parameter values of the equivalent circuit model 30. Parameters of the equivalent circuit model 30 may be used to assess battery condition, predict future voltage, and/or other battery management tasks.

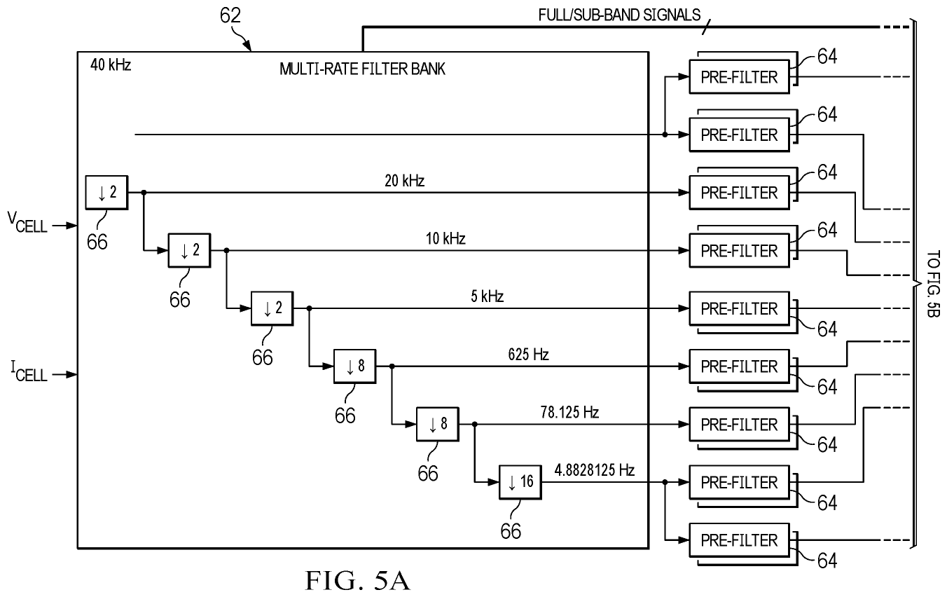

FIG. 4 illustrates a block diagram of a system 50 for online characterization of an equivalent circuit model 30 of battery 12 using sub-bands and augmented dynamic current stimulus, in accordance with embodiments of the present disclosure. System 50 may be implemented as or as a part of battery model estimator 24.

To estimate an impedance model of battery 12, battery model estimator 24 may divide the output impedance of battery 12 into a number of stages or frequency sub-bands 52, each stage/sub-band 52 corresponding to a respective parallel resistive-capacitive section 34 of the equivalent circuit model, thus breaking down the online model estimation 54 into several identification problems of lower order. Such estimation in stages may be possible due to the fact that cutoff frequencies f_{c} (or time constants τ) of the various parallel resistive-capacitive sections, which represent the various electro-chemical processes that occur at different time durations and which represent different electro-chemical processes that happen at a different rate of speed, may be separated by an order of magnitude or more. Further, battery model estimator 24 may, for each particular frequency sub-band 52, monitor, with spectral/signal-to-noise ratio (SNR) sufficiency analyses 56, the quality of prevailing current stimulus I_{CELL} drawn from battery 12 over time and monitor variance of the various equivalent circuit model parameters for such sub-band. Battery model estimator 24 may further implement a decision subsystem 58 that may analyze online model estimations 54 for each sub-band 52, and results of the spectral/SNR analyses 56 for each sub-band 52, to decide whether to generate augmented current stimulus for a particular sub-band 52. If decision subsystem 58 determines to generate augmented current stimulus for a particular sub-band 52, augmented stimulus signal generator 60 may generate a sink current I_{SINK} to supplement current drawn by load 18 in order to draw battery current I_{CELL} with sufficient spectral content to characterize parameters of the equivalent circuit model of battery 12. Sink current I_{SINK} may be based on a dynamic analysis of battery current I_{CELL} and may also be based on an SNR and/or spectral requirement for the equivalent circuit model estimation algorithm performed by battery model estimator 24, in addition to other system-related requirements.

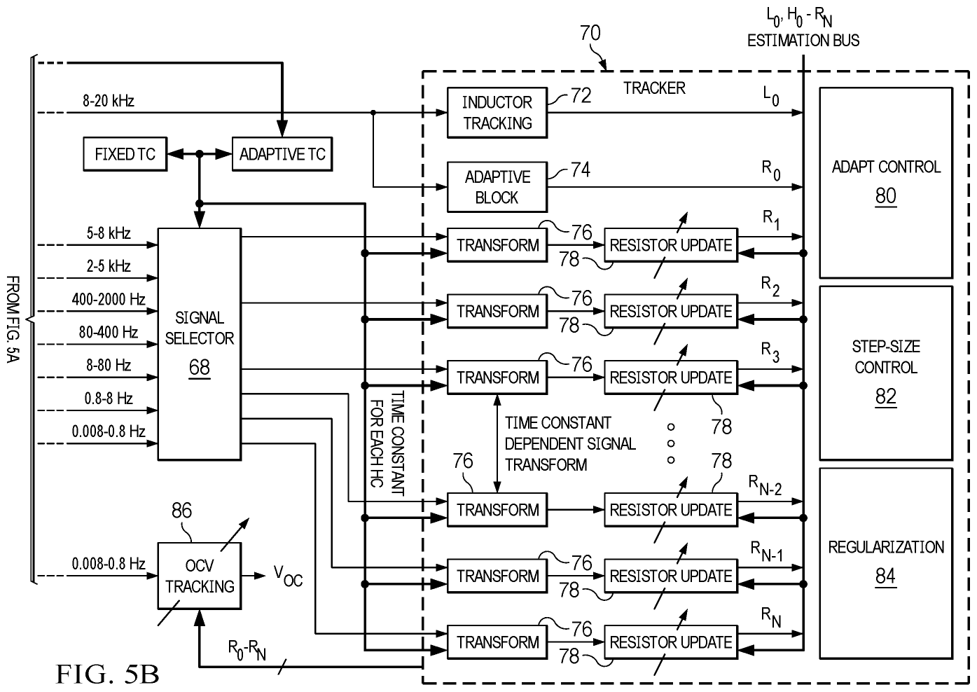

FIGS. 5A and 5B illustrate a block diagram of an example architecture of an algorithm for calculating parameters of an equivalent circuit model of battery 12, in accordance with embodiments of the present disclosure. The functionality of the various blocks depicted in FIGS. 5A and 5B may implement sub-bands 52 and online model estimations 54 shown in FIG. 4.

In accordance with the algorithm depicted in FIGS. 5A and 5B, battery model estimator 24 may measure battery voltage V_{CELL} and battery current I_{CELL}. Battery model estimator 24 may further apply different time constants t that characterize temporal behaviors of battery 12 to decompose (e.g., with multi-rate filter bank 62) the measured battery voltage V_{CELL} and battery current I_{CELL} into sub-bands 52 based on the different time constants τ. Battery model estimator 24 may also continuously track a resistance R within and associated with each of the sub-bands 52, as well as continuously track open circuit voltage V_{OC} of battery 12. The time constants can either be fixed or estimated dynamically from battery voltage V_{CELL} and battery current I_{CELL}.

As shown in FIGS. 5A and 5B, the example architecture comprises a multi-rate filter bank 62 comprising a plurality of decimators 66, pre-filters 64, a signal selector 68, and a tracker 70 arranged as shown.

Multi-rate filter bank 62 is shown in FIG. 5A as having a full band of 40 KHz, but may have any suitable full band range. Further, decimators 66 may each have a decimation rate as shown in FIG. 5A, but may each have a different decimation rate other than that shown in FIG. 5A. Each decimator 66 may respectively decimate battery voltage V_{CELL} and battery current I_{CELL} signals into low-frequency signals. While specific exemplary frequencies are shown associated with decimators 66, any suitable frequencies may be used. The output of each decimator 66 may be communicated to a respective pre-filter 64, and the output of each pre-filter 64 may represent various sub-bands 52 into which the full band of battery voltage V_{CELL} and battery current I_{CELL} signals is divided. For example, FIG. 5B shows the full band divided into sub-bands of 8-20 KHz, 5-8 KHz, 2-5 KHz, 400-2500 Hz, 800-400 Hz, 8-80 Hz, 0.8-8 Hz, 0.008-0.8 Hz, and 0-0.008 Hz, although any suitable ranges may be used for the various sub-bands 52.

A fixed time constant or an adaptive time constant for each parallel resistive-capacitive section 34 may be received by signal selector 68. A fixed time constant may be based on a set of pre-stored values. An adaptive time constant may be computed dynamically through an adaptive algorithm that uses battery voltage V_{CELL} and battery current I_{CELL} and/or the adaptive time constant may be selected from a look-up table whose indices are selected based on the battery state of charge and/or temperature.

As depicted in FIG. 5B, tracker 70 may perform inductor tracking 72 based on the output of pre-filter 64 representing the highest-frequency sub-band 52 in order to estimate an inductive value L₀ (not shown in FIG. 5) that models an equivalent resistance in series with equivalent series resistance 36 of battery 12 and an equivalent circuit model of battery 12. Tracker 70 may also include an adaptive block 74 (e.g., a recursive-least squares, total-least squares, normalized least-mean-squares, total least squares cost function, and/or different variants of gradient descent based algorithms) that outputs resistive value R₀ for the equivalent circuit model of battery 12 based on the output of pre-filter 64 representing the highest-frequency sub-band 52.

The outputs of the remaining pre-filters 64 may be provided as inputs to signal selector 68. As shown in FIGS. 5A and 5B, a plurality of different time constants, which may be distributed such that they cover an entire spectral range of interest and overall time constant value, may be received by signal selector 68. Signal selector 68 may select, for each transform 76/resistor update 78 pair of tracker 70, a signal from an output of pre-filter 64 based on the time constants. In particular, signal selector 68 may select an appropriate signal from multi-rate filter bank 62 such that spectral coverage of the selected signal includes the frequency corresponding to the respective time constant.

Tracker 70 may further include a plurality of transform 76/resistor update 78 pairs that may calculate respective resistive values R₁, . . . , R_{N} of the equivalent circuit model of battery 12. For example, in some embodiments, battery model estimator 24 may calculate respective resistive values R₁, . . . , R_{N} of the equivalent circuit model of battery 12 in a manner similar to that disclosed in U.S. patent application Ser. No. 17/463,980, filed Sep. 1, 2021, and incorporated by reference herein. For example, resistor update blocks 78 may continuously update resistances representing each sub-band 52 using an adaptive algorithm, implemented by adapt control block 80 of tracker 70, using a recursive-least squares, a total-least squares, a normalized least-mean-squares, or other suitable approach. In some embodiments, parameters of the equivalent circuit model of battery 12 may be updated by a resistor update block 78: (a) when a full-band current root-mean-square level is above a threshold, (b) such that a sub-band error is minimized; or (c) jointly such that a full band error is minimized. A learning rate of the update algorithm may be based on a sub-band root-mean-square current level. In some embodiments, resistor update blocks 78 may be constrained to calculate only positive resistance values.

Tracker 70 may also include a step-size control block 82. If the adaptive algorithm implemented by adapt control block 80 includes a family of gradient descent based algorithms, then step-size control block 82 may dynamically calculate the learning rate or step size of such algorithm to ensure faster convergence of the parameters while not drifting away from the true value.

Tracker 70 may also include a regularization block 84. Due to the dynamic nature of the signal and also the varying signal-to-noise ratio conditions, it is important that the adaptive algorithm does not diverge too much from the true solution. Regularization block 84 may avoid the problem of overfitting, which may occur when the adaptive algorithm adapts during low signal-to-noise ratio conditions and tries to minimize the modelling error even though the background noise dominates the signal.

The algorithm may also include an open-circuit voltage (OCV) tracking block 86 configured to adaptively estimate open-circuit voltage V_{OC} based on an input received from pre-filter 64 representing the lowest-frequency sub-band 52 and the various resistive values R₁, . . . , R_{N} of the equivalent circuit model of battery 12. For example, OCV tracking block 86 may, based on the output of the lowest-frequency pre-filter 64 and tracked resistances of the equivalent circuit model for battery 12, continuously update an estimated open-circuit voltage V_{OC} using an adaptive algorithm (e.g., a recursive-least squares, total-least squares, normalized least-mean-squares). In some embodiments, the OCV may be provided by another estimator or algorithm, such as from a fuel gauge solution.

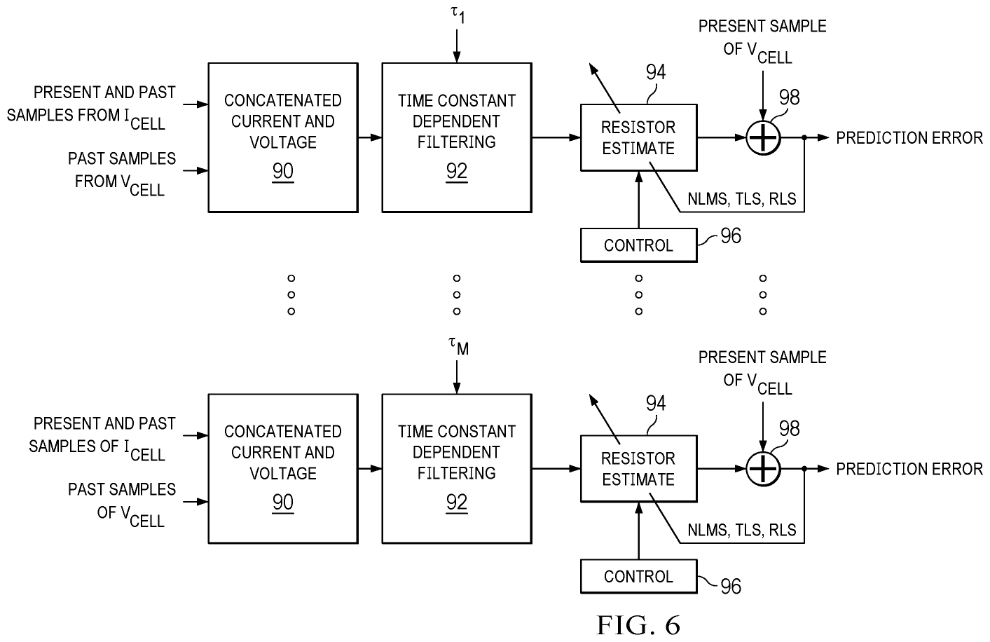

FIG. 6 illustrates a block diagram of an example architecture of tracker 70 for calculating parameters of the equivalent circuit model of battery 12, in accordance with embodiments of the present disclosure. The architecture shown in FIG. 6 may implement transform blocks 76 and resistor update blocks 78 shown in FIGS. 5A and 5B.

FIG. 6 depicts 1 to M number of paths that process battery voltage V_{CELL} and battery current I_{CELL} signals decomposed into sub-bands 52 as described above. Each processing path may include a concatenated current & voltage block 90, time constant dependent filtering block 92, a resistor estimate block 94, a control block 96, and a summer 98 arranged as shown in FIG. 6. Each concatenated current & voltage block 90 may receive as its input the present and past sample values of battery current I_{CELL} and the past sample values of battery voltage V_{CELL} for the given sub-band 52. Time-constant dependent filtering block 92 may receive the output from its respective concatenated current & voltage block 90 and a time constant Ti for the given sub-band 52. Such filtering may be performed in order to convert the non-linear optimization problem into a linear optimization problem. The original equivalent circuit model identification problem involves estimating either resistor and capacitor or resistor and time constant. Estimating them jointly is a non-linear optimization problem, and it is not suited to be done in embedded applications. Therefore, such filtering may simplify the problem into a linear problem by assuming apriori knowledge of the time constants. The time constants can be determined by offline characterization of a battery, or they can be dynamically estimated by a separate time constant estimation block.

Control block 96 may be configured to provide an indication to the adaptive algorithm that the signal conditions are sufficient enough to update the resistive values (e.g., R₁, . . . , R_{N}) of its associated resistor estimate block 94. Each resistor estimate block 94 may provide an estimated present sample of battery voltage V_{CELL} for its respective sub-band 52. Combiner 98 may compare the true sample to the predicted present sample to generate a prediction error. Such prediction error may then be used in the parameter update equation of the adaptive filter. Controller 96 may control an update algorithm to control resistor estimate block 94 to minimize the prediction error.

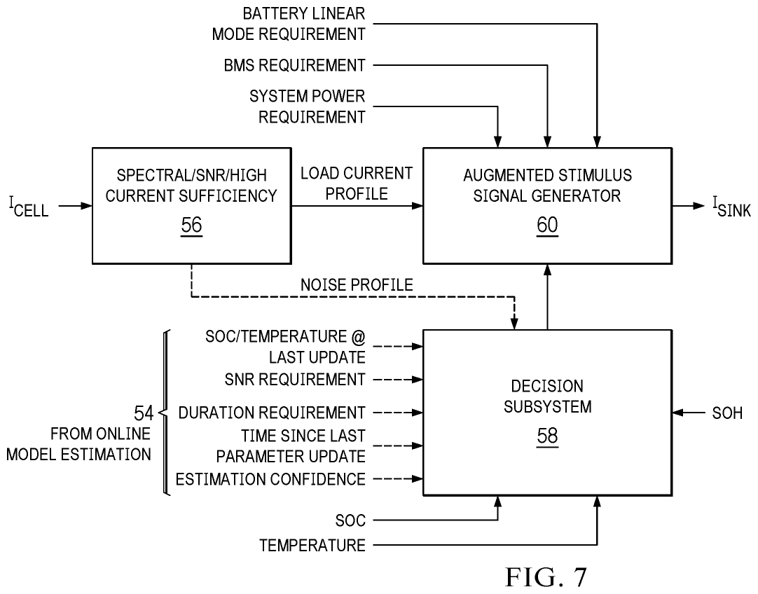

FIG. 7 illustrates a block diagram of selected components of system 50, in accordance with embodiments of the present disclosure. In particular, FIG. 7 depicts more detail demonstrating operability among spectral/SNR sufficiency analysis block 56, decision subsystem 58, and augmented stimulus signal generator 60.

When a system load current is present (e.g., when load 18 draws a current from battery 12), the generation of augmented stimulus in the form of sink current I_{SINK} may be performed on a sub-band basis. Decision subsystem 58 may determine an aggregate stimulus requirement within each sub-band based on state-of-charge (SOC) and temperature conditions during the last update of model parameters for the respective sub-band compared with prevailing SOC and temperature conditions (i.e., to determine if any changes to SOC and/or temperature have occurred requiring parameter updates). In addition, decision subsystem 58 may also receive a noise profile from spectral/SNR sufficiency analysis block 56, which may continuously evaluate current within each sub-band for spectral sufficiency and noise. Thus, decision subsystem 58 may also determine the aggregate stimulus requirement within each sub-band based on such noise profile, an SNR requirement for the sub-band, a duration of signal required in the sub-band in order to calculate parameters associated with such sub-band (which may vary among sub-bands), an amount of time that has passed since a previous parameter update for the sub-band, and an estimation confidence for the sub-band. For example, spectral/SNR sufficiency analysis block 56 may analyze battery current I_{CELL} to estimate the prevailing SNR in each sub-band, and decision subsystem 58 may use such SNR information to modify a level of stimulus for such sub-band accordingly. Decision subsystem 58 may also determine the aggregate stimulus requirement within each sub-band based on a state of health (SOH) of battery 12. Decision subsystem 58 may also employ one or more power saving schemes in the decision-making process of determining aggregate stimulus requirement. For example, model parameters in some frequency ranges may not change due to SOC and/or temperature changes, and thus, decision subsystem 58 may limit augmented current generation for such sub-bands to conditional triggers other than SOC and/or temperature changes.

Based on the aggregate stimulus requirement determined by decision subsystem 58, a system power requirement, a battery management system requirement, a battery linear mode requirement, and/or other factors, augmented stimulus signal generator 60 may generate sink current I_{SINK} for each particular sub-band. Generally speaking, augmented stimulus signal generator 60 (in concert with decision subsystem 58) may track absolute current, and if current is above a particular threshold, may cause adaptation of equivalent circuit model parameters to be disabled. However, if an absolute current requirement is not met over time, augmented stimulus signal generator 60 may cause generation of a low-level sink current I_{SINK} to be generated such that equivalent circuit model parameters are estimated in a linear range of the operating condition of battery 12.

As briefly mentioned above, generation of sink current I_{SINK} may be conditioned on various factors and conditions. For example, in some embodiments, existence of one or more of the following conditions within a sub-band may be required in order to trigger generation of augmented sink current I_{SINK} for such sub-band:
A significant change in SOC and the absence of sufficient load current in one of the sub-bands or the full band for a preset period of time;
A significant change in temperature without significant load current in a sub-band or the full band since the last validated update of equivalent circuit model parameters;
Fitting performance of a continuously tracked model has drifted without significant load current in a sub-band or the full band for a preset period of time;
Significant change in root-mean-square value of current over a preset period of time;
A rate of change of averaged battery voltage V_{CELL} significantly changing over a preset period of time; and
Root-mean-square value of current falls below a threshold for a period of time.

The foregoing describes approaches for maintaining and updating parameters of a linear equivalent circuit model 30 for battery 12. However, a battery is a highly dynamic and non-linear system. In addition to temperature, state of charge, and state of health, impedance of a battery may also vary as a function of a current drawn from it. Thus, to ensure accuracy, a battery model may need to be non-linear because the model parameters may also change as a function of current amplitude.

For predictive purposes, equivalent circuit model parameters for a linear model estimated at a certain dynamic load level may not result in accurate voltage prediction when prediction is performed at much higher current levels.

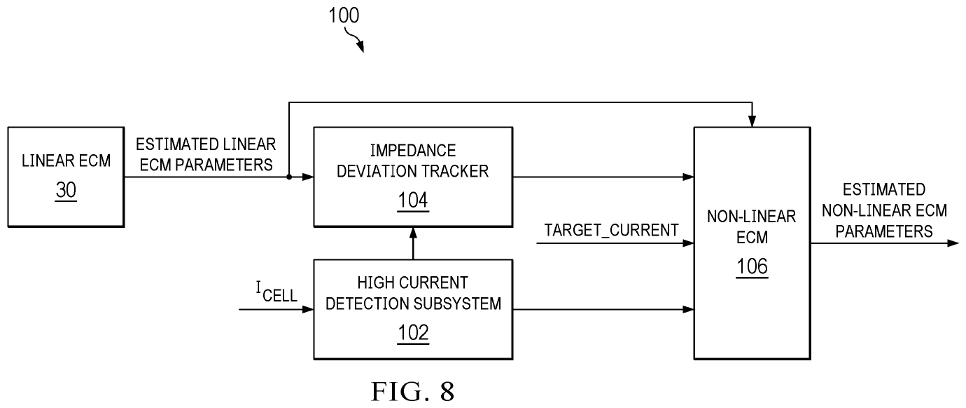

FIG. 8 illustrates a high-level block diagram of selected components of a system 100 for online characterization of a current-dependent non-linear equivalent circuit model of battery 12, in accordance with embodiments of the present disclosure. System 100 may be implemented in whole or part by battery model estimator 24. As shown in FIG. 8, system 100 may include linear equivalent circuit model (ECM) 30, high-current detection subsystem 102, impedance deviation tracker 104, and non-linear ECM 106. In operation of system 100, linear ECM parameters estimated by linear ECM 30 may be converted into current-dependent non-linear ECM 106.

High current detection subsystem 102 may continuously monitor battery current I_{CELL}. In a typical use case scenario, battery current I_{CELL} may predominantly include long-duration, low-current regions with occasional short-duration, high-current signals that appear in a burst mode. High current detection subsystem 102 may detect these bursty high current events and record the time of these high-current events. In addition, high current detection subsystem 102 may also record the average current during the burst event. Once the high current events are detected, impedance deviation tracker 104 may track quick changes in impedance of battery 12 due to high current events as changes in the resistive-capacitive (RC) pair parameters of linear ECM 30. System 100 may store ECM parameters preceding the high current events and the corresponding average current during the times preceding the high current events for further estimation of non-linear ECM parameters.

As used herein, a “high current event” may occur when an average or root-mean-square value of a discharge current of battery 12 is above a particular threshold (e.g., 2 A) for a pre-specified period of time.

If a high current is not present in the dynamic load for a pre-specified period of time, then a short duration high current may be augmented using sink current I_{SINK}, and a non-linear impedance deviation may be estimated from this short duration high current pulse, for example in a manner described in U.S. Provisional Patent Application Ser. No. 63/606,389, filed Dec. 5, 2023, which is incorporated by reference herein in its entirety.

Impedance deviation tracker 104 may estimate changes in the RC-pair impedances of linear ECM 30 by computing the difference between the impedance estimated during the high current event and the impedance estimated during the time preceding the high current event. Impedance deviation tracker 104 may continuously monitor and store the changes in the impedance and the corresponding high current average value.

Non-linear ECM 106 may continuously estimate an online interpolating curve from all the measurement sets in order to interpolate/extrapolate changes in the impedance at current amplitudes that are in the range outside of the measurement set. Thus, this interpolating function may be continuously modified in an online manner to account for changes due to variations in battery state of charge, temperature, and state of health. Non-linear ECM 106 may also combine the current dependent resistance change with the RC-pair impedance that is estimated by linear ECM 30 during non-high current events to obtain a current dependent non-linear ECM parameter set.

As shown in FIG. 8, non-linear ECM 106 receives a signal TARGET_CURRENT as an input. To illustrate, if an impedance spectral function for battery 12 is represented as Z (f) where f is the frequency, then Z (f) is typically a linear impedance function wherein the impedance function does not change as a function of input current level. However, as described herein, battery 12 is a non-linear system. Therefore, non-linear ECM 106 may approximate the non-linear impedance function as a current-dependent impedance function represented as Z(f,I), where I is represented by signal TARGET_CURRENT. Thus, for a given input current level, non-linear ECM 106 may have a corresponding impedance function.

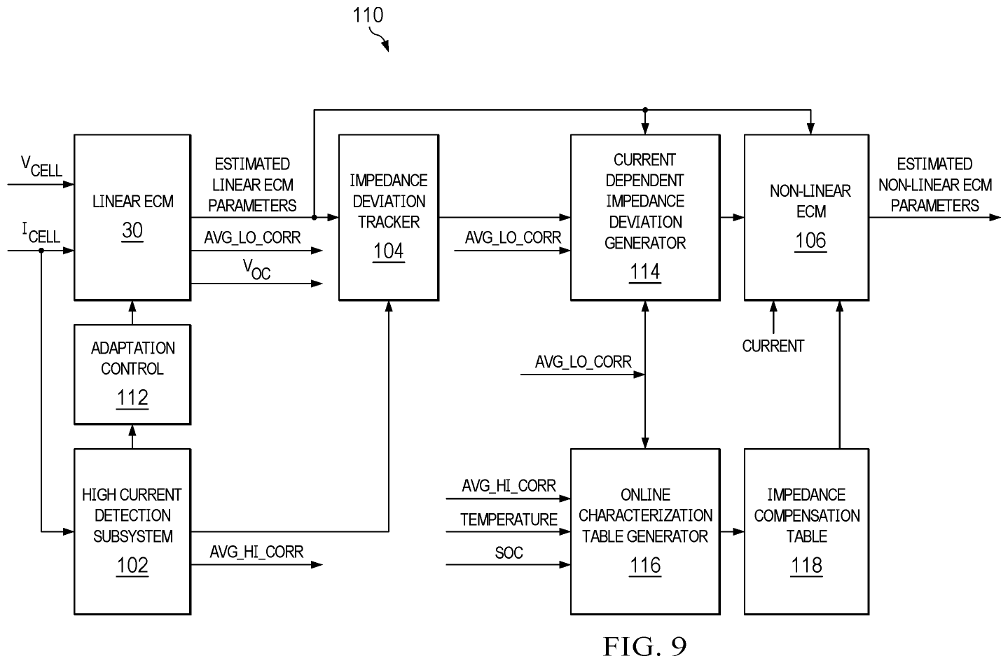

FIG. 9 illustrates a detailed-level block diagram of selected components of a system 110 for online characterization of a current-dependent non-linear equivalent circuit model of battery 12, in accordance with embodiments of the present disclosure. In some embodiments, system 110 may be used to implement system 100 depicted in FIG. 8. As shown in FIG. 9, system 110 may include linear ECM 30, high current detection subsystem 102, impedance deviation tracker 104, non-linear ECM 106, adaptation controller 112, current-dependent impedance deviation generator 114, online characterization table generator 116, and impedance compensation table 118.

In operation of system 110, linear ECM parameters estimated by linear ECM 30 may be converted into current-dependent non-linear ECM 106 which may output non-linear ECM parameters. In addition to linear ECM parameters, linear ECM 30 may also output an average current AVG_LO_CURR and battery open-circuit voltage V_{OC}.

As above, high current detection subsystem 102 may continuously monitor battery current I_{CELL} and detect and record high current events. In addition, high current detection subsystem 102 may also record the average current AVG_HI_CURR during the burst event. Via adaptation controller 112, changes in RC-pair parameters of linear ECM 30 may occur in response to the high current events, and impedance deviation tracker 104 may track quick changes in impedance of battery 12 due to high current events as changes in the RC-pair parameters of linear ECM 30. In some embodiments, adaptation controller 112 may modify an adaptation rate of linear ECM 30 when a high current event is detected.

Impedance deviation tracker 104 may estimate changes in the RC-pair impedances of linear ECM 30 by computing the difference between the impedance estimated during the high current event and the impedance estimated during the time preceding the high current event.

Based on average current AVG_HI_CURR during the burst event, the average current AVG_LO_CURR preceding the burst event, deviations calculated by impedance deviation tracker 104, and linear ECM 30 parameters, current dependent deviation impedance deviation generator 114 may continuously estimate an online interpolating curve from all the measurement sets in order to interpolate/extrapolate changes in the impedance at current amplitudes that are in the range outside of the measurement set.

System 110 may store ECM parameters preceding the high current events and the corresponding average current during the times preceding the high current events for further estimation of non-linear ECM parameters. System 110 may also continuously monitor and store the changes in the impedance and the corresponding high current average value.

Online characterization table generator 116 may continuously update impedance compensation table 118 (e.g., a lookup table) to store and continuously modify impedance compensation values due to variations in battery state of charge, temperature, and state of health.

Non-linear ECM 106 may also combine the current dependent resistance change with the RC-pair impedance that is estimated by linear ECM 30 during non-high current events, and based on information from other components of system 110, obtain a current dependent non-linear ECM parameter set.

To further illustrate the functionality of FIG. 9 in generating impedance compensation table 118, impedance compensation table 118 may be maintained at a set of SOCs (e.g., for every 5% SOC) and temperature (e.g., every) 5°. An example of impedance compensation table 118 is set forth below.

| Current\Resistance | ΔR₀ | ΔR₁ | ΔR₂ | | ΔR_{N} |
|---|---|---|---|---|---|
| of RC pair | (Ω) | (Ω) | (Ω) | . . . | (Ω) |
| 2 A | | | | | |
| 2.1 A | | | | | |
| . | | | | | |
| . | | | | | |
| . | | | | | |
| 20 A | | | | | |

At a given time instant with a prevailing SOC and temperature, the non-linear ECM block 106 takes the current independent linear ECM parameters as input and adjusts the corresponding linear ECM parameters using the compensation value stored in the online characterization table. For example, for an ECM model, impedance compensation table 118 may include resistance/capacitance compensation values.

To further illustrate, if impedance at a particular TARGET_CURRENT is given as:

$${R}_{i} ( TARGET\_CURRENT ) = {R}_{i} ( Linear ECM ) - Δ {R}_{i} ( TARGET\_CURRENT , SOC , Temp )$$

then the overall current dependent impedance may be calculated as:

$$Z ( ω , TARGET\_CURRENT ) = {R}_{0} ( TARGET\_CURRENT ) + {\sum }_{m = 1}^{M} \frac{{R}_{m} ( TARGET\_CURRENT )}{1 + j ω {R}_{m} ( TARGET\_CURRENT ) {C}_{m}}$$

Thus, non-linear ECM 106 may provide a set of current dependent ECM parameters at the prevailing SOC and temperature.

Embodiments of the present disclosure thus provide methods and systems to estimate current dependent non-linear equivalent circuit model (ECM) parameters of a battery in a system configured to provide a load. A sense current and a terminal voltage of a battery may be measured, and different time constants that characterize temporal behaviors of the battery may be obtained and/or used. The ECM may be comprised of a set of N number of RC pairs wherein N is an integer equal to one or greater. The RC pair values may be estimated by reducing an error between the terminal voltage and the fitted voltage. In one embodiment, the time constants of each RC pair may be chosen apriori and only the resistance of each RC pair may be estimated using an adaptive algorithm. In another embodiment, the current and voltage may be decomposed into sub-bands, and the resistance of each RC pair may be continuously tracked within each sub band. An open circuit voltage of the battery may also be continuously tracked.

Linear ECM parameters may be derived to model a linear ECM by using multiple RC-elements with different time constants that characterize temporal behaviors of the battery. A sense current may be continuously monitored to detect high current events. A deviation for each RC-pair impedance during the high current events may be continuously tracked. Non-linear online ECM parameters may be derived using the linear ECM parameters and the RC-pair impedance deviations at all current amplitudes.

The RC-pair impedance deviations at all current levels may be interpolated and/or extrapolated from RC-pair impedance deviations computed during the low current regions and the detected high current regions. The impedance deviations at all current amplitudes may be interpolated and/or extrapolated using different variants of non-linear mapping functions. The RC-pair impedance and the impedance deviations may be calculated using an adaptive algorithm. The method may be an adaptive algorithm, and an adaptation rate of the adaptive algorithm may be dynamically changed whenever the high current region is detected. The tracked deviations at different high current amplitudes from past time samples from the continuous tracking of a deviation step may be stored and then used during an interpolation/extrapolation step. The high current regions may be detected whenever a root-mean-square (RMS) current and/or a maximum instantaneous current are above some thresholds.

The current dependent non-linear ECM parameters may be used to determine available power that the battery is able to support before the terminal voltage of the battery reaches a pre-determined brown-out voltage. The current dependent non-linear ECM parameters may be used to determine a maximum current that is able to be drawn from the battery for a sustained period of time before the terminal voltage of the battery reaches a pre-determined brown-out voltage. The current dependent non-linear ECM parameters may be used to determine available energy that the battery is able to sustain before the terminal voltage of the battery reaches a pre-determined brown-out voltage. The different time constants may be continuously tracked. The continuous tracking of the impedance may be accomplished by using an adaptive algorithm such as a Normalized Least Means Square (NLMS) algorithm, a Total Least Squares (TLS) algorithm, or a Recursive Least Squares (RLS) algorithm. A load current drawn by the load may be used as the sense current.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method for estimating current-dependent non-linear equivalent circuit model (ECM) parameters of a battery, comprising:
measuring a battery voltage across terminals of the battery and a battery current drawn from the battery;
deriving linear ECM parameters for modeling a linear ECM of the battery with multiple resistive-capacitive elements with different time constants to characterize temporal behaviors of the battery;
continuously tracking an impedance for each of the multiple resistive-capacitive elements and an open circuit voltage of the battery;
continuously monitoring the battery current to detect high current events;
continuously tracking a deviation for each of the multiple resistive-capacitive elements during the high current events; and
deriving non-linear online ECM parameters based on the linear ECM parameters and the deviations for the multiple resistive-capacitive elements during the high current events.

2. The method of claim 1, wherein the deviations at certain current levels are interpolated or extrapolated from an average current drawn from the battery during high current events and an average current drawn from the battery in the absence of high current events.

3. The method of claim 1, further comprising calculating impedances of the multiple resistive-capacitive elements and the deviations of the multiple resistive-capacitive elements using an adaptive algorithm.

4. The method of claim 1, wherein deriving linear ECM parameters and deriving non-linear online ECM parameters is performed by an adaptive algorithm, and an adaptation rate of the adaptive algorithm is changed during high current events.

5. The method of claim 1, wherein the high current event comprises an average of instantaneous value of the battery drawn from the battery exceeding a threshold.

6. The method of claim 1, further comprising determining an available power that can be drawn from the battery for a given period of time before the battery voltage decreases to a brown-out voltage based on the linear online ECM parameters.

7. The method of claim 1, further comprising determining a maximum current that can be drawn from the battery for a given period of time before the battery voltage decreases to a brown-out voltage based on the linear online ECM parameters.

8. The method of claim 1, further comprising determining an energy that the battery can sustain before the battery voltage decreases to a brown-out voltage based on the linear online ECM parameters.

9. The method of claim 1, further comprising, in the absence of detection of high-current events:
augmenting the battery current with a sink current to generate an augmented current;
continuously tracking the deviation for each of the multiple resistive-capacitive elements based on the augmented current; and
deriving non-linear online ECM parameters based on the linear ECM parameters and the deviations for the multiple resistive-capacitive elements based on the augmented current.

10. The method of claim 1, further comprising maintaining online updating of a characterization table that sets forth values for the deviation for each of the multiple resistive-capacitive elements at different current amplitudes for a given state of charge and temperature associated with the battery.

11. A method for modelling an equivalent circuit for a battery, comprising:
determining equivalent circuit model (ECM) parameters to model the battery wherein the ECM parameters include current-dependent non-linear online ECM parameters; and
deriving the current dependent non-linear online ECM parameters by using linear ECM parameters and resistive-capacitive (RC) pair impedance deviation estimates for RC pairs of the ECM multiple amplitudes of the current wherein the RC pair impedance deviation estimates are determined by continuously tracking an impedance and an impedance deviation for each RC pair.

12. A method for estimating current-dependent non-linear equivalent circuit model (ECM) parameters of a battery, comprising:
measuring a battery voltage across terminals of the battery and a battery current drawn from the battery;
deriving linear ECM parameters for modeling a linear ECM of the battery with multiple resistive-capacitive elements with different time constants to characterize temporal behaviors of the battery;
continuously tracking an impedance for each of the multiple resistive-capacitive elements and an open circuit voltage of the battery;
continuously monitoring the battery current to detect high current events; and
in the absence of detection of high-current events:
augmenting the battery current with a sink current to generate an augmented current;
continuously tracking the deviation for each of the multiple resistive-capacitive elements based on the augmented current; and
deriving non-linear online ECM parameters based on the linear ECM parameters and the deviations for the multiple resistive-capacitive elements based on the augmented current.

13. A system for estimating current-dependent non-linear equivalent circuit model (ECM) parameters of a battery, comprising:
measurement circuitry for measuring a battery voltage across terminals of the battery and a battery current drawn from the battery;
a linear ECM for deriving linear ECM parameters to model the linear ECM of the battery with multiple resistive-capacitive elements with different time constants to characterize temporal behaviors of the battery;
a high-current detection subsystem for continuously monitoring the battery current to detect high current events;
an impedance deviation tracker for:
continuously tracking an impedance for each of the multiple resistive-capacitive elements and an open circuit voltage of the battery; and
continuously tracking a deviation for each of the multiple resistive-capacitive elements during the high current events; and
a non-linear ECM for deriving non-linear online ECM parameters based on the linear ECM parameters and the deviations for the multiple resistive-capacitive elements during the high current events.

14. The system of claim 13, wherein the deviations at certain current levels are interpolated or extrapolated from an average current drawn from the battery during high current events and an average current drawn from the battery in the absence of high current events.

15. The system of claim 13, wherein the impedance deviation tracker is further for calculating impedances of the multiple resistive-capacitive elements and the deviations of the multiple resistive-capacitive elements using an adaptive algorithm.

16. The system of claim 13, wherein deriving linear ECM parameters and deriving non-linear online ECM parameters is performed by an adaptive algorithm, and an adaptation rate of the adaptive algorithm is changed during high current events.

17. The system of claim 13, wherein the high current event comprises an average of instantaneous value of the battery drawn from the battery exceeding a threshold.

18. The system of claim 13, wherein the non-linear ECM is further for determining an available power that can be drawn from the battery for a given period of time before the battery voltage decreases to a brown-out voltage based on the linear online ECM parameters.

19. The system of claim 13, wherein the non-linear ECM is further for determining a maximum current that can be drawn from the battery for a given period of time before the battery voltage decreases to a brown-out voltage based on the linear online ECM parameters.

20. The system of claim 13, wherein the non-linear ECM is further for determining an energy that the battery can sustain before the battery voltage decreases to a brown-out voltage based on the linear online ECM parameters.

21. The system of claim 13, further comprising, in the absence of detection of high-current events:
a dependent current source for augmenting the battery current with a sink current to generate an augmented current;
the impedance deviation tracker further for continuously tracking the deviation for each of the multiple resistive-capacitive elements based on the augmented current; and
the non-linear ECM for further deriving non-linear online ECM parameters based on the linear ECM parameters and the deviations for the multiple resistive-capacitive elements based on the augmented current.

22. The system of claim 13, further comprising a current dependent impedance deviation generator maintaining online updating of a characterization table that sets forth values for the deviation for each of the multiple resistive-capacitive elements at different current amplitudes for a given state of charge and temperature associated with the battery.

23. A system for modelling an equivalent circuit for a battery, comprising:
an equivalent circuit model (ECM) for determining ECM parameters to model the battery wherein the ECM parameters include current-dependent non-linear online ECM parameters; and
a non-linear ECM for deriving the current dependent non-linear online ECM parameters by using linear ECM parameters and resistive-capacitive (RC) pair impedance deviation estimates for RC pairs of the ECM multiple amplitudes of the current wherein the RC pair impedance deviation estimates are determined by continuously tracking an impedance and an impedance deviation for each RC pair.

24. A method for estimating current-dependent non-linear equivalent circuit model (ECM) parameters of a battery, comprising:
measurement circuitry for measuring a battery voltage across terminals of the battery and a battery current drawn from the battery;
a linear ECM for deriving linear ECM parameters to model the linear ECM of the battery with multiple resistive-capacitive elements with different time constants to characterize temporal behaviors of the battery;
an impedance deviation tracker for continuously tracking an impedance for each of the multiple resistive-capacitive elements and an open circuit voltage of the battery;
a high-current detection subsystem for continuously monitoring the battery current to detect high current events;
in the absence of detection of high-current events:
a dependent current source for augmenting the battery current with a sink current to generate an augmented current;
the impedance deviation tracker further for continuously tracking the deviation for each of the multiple resistive-capacitive elements based on the augmented current; and
the non-linear ECM for further deriving non-linear online ECM parameters based on the linear ECM parameters and the deviations for the multiple resistive-capacitive elements based on the augmented current.
